(19) United States
(12) Patent Application Publication
(10) Pub. No.: US 2016/0293787 A1
(43) Pub. Date: Oct. 6, 2016

(54) Nanostructured window layer in solar cells

(71) Applicant: THE BOARD OF TRUSTEES OF THE LELAND STANFORD JUNIOR UNIVERSITY, Palo Alto, CA (US)

(72) Inventors: Dong Liang, Fremont, CA (US); Yangsen Kang, Stanford, CA (US); Yijie Huo, Cupertino, CA (US); James S. Harris, JR., Stanford, CA (US)

(21) Appl. No.: 14/442,133

(22) PCT Filed: Nov. 12, 2013
(86) PCT No.: PCT/US13/69645

§ 371 Date: May 12, 2015

Related U.S. Application Data
(60) Provisional application No. 61/725,084, filed on Nov. 12, 2012.

(51) Int. Cl. H01L 31/0468; H01L 31/0224; H01L 31/0216

(52) U.S. Cl. CPC H01L 31/0468; H01L 31/02168; H01L 31/022433

(57) ABSTRACT

A solar cell has a nanostructured window layer with planar p-n junction geometry. Preferably, metal grid mesas are used to provide lateral conductance and good electrical contacts. In addition to carrier confinement and lateral conductance, this window layer can also provides a broadband angle-independent antireflection function. This structure enhances both the optical and electrical properties in a solar cell, leading to higher J_{sc}, V_{oc}, FF (fill factor) and efficiency. The absorption in the window layer is partially converted to photocurrent, which to some extent compensates for the self-absorption loss due to its greater thickness. This design can eliminate the need for a separate anti-reflection coating.

### FIELD OF THE INVENTION

This invention relates to solar cells.

### BACKGROUND

Nanostructures have been widely used in solar cells to enhance light absorption and facilitate charge separation. A large variety of nanostructures have been applied to many layers in different types of solar cells, such as antireflection coatings, light trapping absorbers, core-shell lateral junctions and back surface reflectors. One of the main challenges of most of these approaches is formation of high-quality p-n junctions and good electrical contacts.

### SUMMARY

In this work, a nanostructured window layer is combined with a planar junction geometry to alleviate the above-cited difficulties with electrical contacts and p-n junction quality. Window layers are usually transparent to shorter wavelengths than the active region of the device and are most often used to provide carrier confinement. Window layers are widely used in a variety of optoelectronic devices, such as solar cells, LEDs (light emitting diodes) and detectors. In a conventional solar cell, the window layer (if present) is usually a quasi-transparent conducting layer with a large band gap, sandwiched between the antireflection layer and the emitter. It is most often seen in compound semiconductor solar cell devices, such as III-V, CdTe and CIGS (copper-indium-gallium-selenide) solar cells. By providing increased lateral conductivity, the window layer can reduce solar cell series resistance. More importantly, they create a potential barrier that reflects the minority carriers coming toward the cell top surface back toward the electric field created by the p-n junction, thereby reducing the loss of light generated carriers due to surface recombination. Typical window layer materials include CdS, ZnS and ZnO for CdTe and CIGS solar cells, Al_{0.8}Ga_{0.2}As and In_{0.51}Ga_{0.49}P for GaAs solar cells, etc. Ideally, a window layer is lattice matched to the rest of the solar cell and is highly transparent across the whole solar spectrum. Practically, due to its finite band gap, photons with energy above the window layer band gap are inevitably absorbed by the window layer itself. In order to minimize this self-absorption, the window layer thickness is typically less than 100 nm. However, if their band gap is sufficiently large, thick window layers up to several micrometers is also acceptable. For example, ZnO can be several micrometers thick on thin film a-Si solar cells. In another scenario, if the absorbed light in the window layer can be converted into photo current, it can be relatively thick to provide sufficient lateral conductance and minority carrier confinement. Therefore, there is plenty of room to engineer the window layer to further extend its functionality.

In this work, we introduce a hybrid structure that combines a nanostructured window layer with planar p-n junction geometry. Preferably, metal grid mesas are used to provide lateral conductance and good electrical contacts. In addition to carrier confinement and lateral conductance, this window layer can also provide a broadband angle-independent antireflection function. This structure enhances both the optical and electrical properties in a solar cell, leading to higher J_{sc}, V_{oc}, FF (fill factor) and efficiency. The absorption in the window layer is partially converted to photocurrent, which to some extent compensates for the self-absorption loss due to its greater thickness. This design eliminates the need of multi-layer anti-reflection deposition, such as MgF₂/ZnS bilayer coating for GaAs solar cells.

### BRIEF DESCRIPTION OF THE DRAWINGS

FIG. 1 shows an exemplary side view of an embodiment of the invention.

FIG. 2 shows an exemplary top view of an embodiment of the invention.

FIG. 3 is a cross section scanning electron microscope (SEM) image of a metal grid mesa part of a fabricated device.

FIG. 4 is a cross section SEM image of a nano-structure part of a fabricated device.

FIG. 5 shows measured optical absorption in a nano-structured solar cell compared to an analogous planar solar cell.

FIG. 6 shows measured J-V curves in a nano-structured solar cell compared to an analogous planar solar cell.

FIG. 7 shows measured external quantum efficiency (EQE) in a nano-structured solar cell compared to an analogous planar solar cell.

FIG. 8 shows simulated contributions to the EQE of the nano-structured device of FIG. 7 from the window layer and from the active region.

### DETAILED DESCRIPTION

In this description, section A describes general principles of embodiments of the invention, and section B provides an experimental demonstration.

### A) General Principles

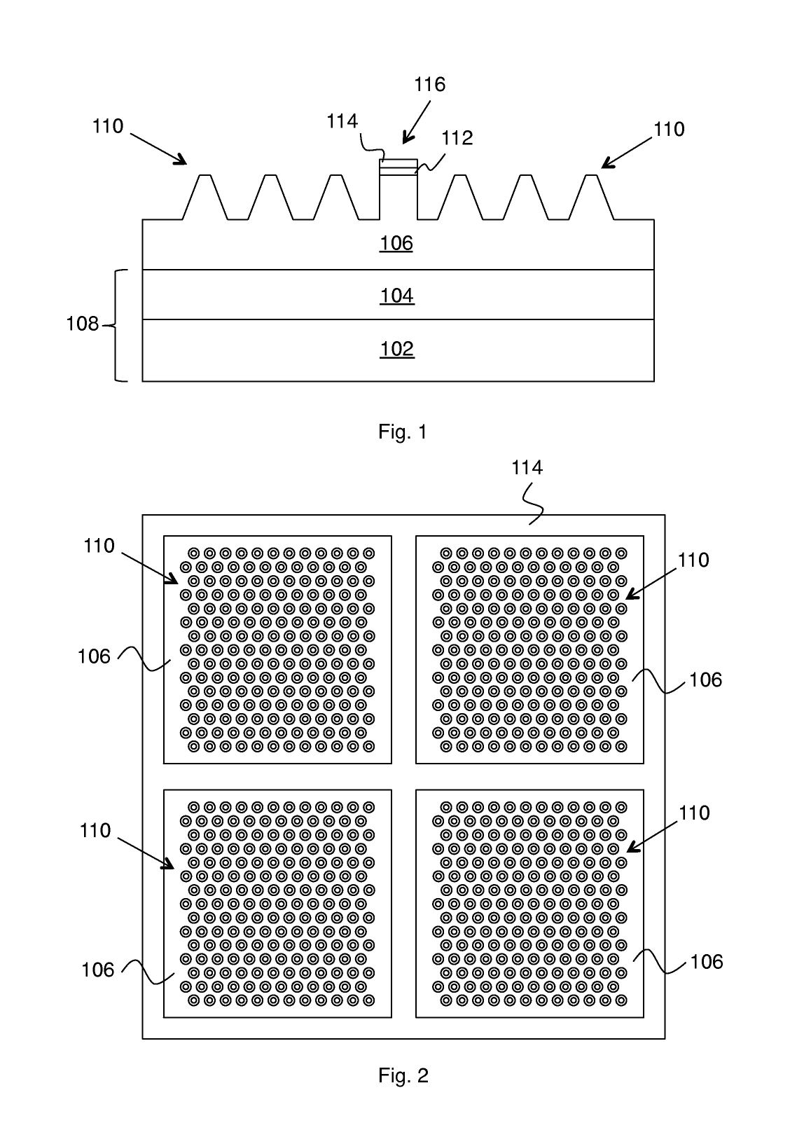

FIG. 1 shows an exemplary embodiment of the invention. This example is a solar cell having a semiconductor active region 108, where optical absorption in the active region provides electrical charge carriers. A semiconductor window layer 106 is disposed on the active region such that light incident on the active region passes through the window layer (i.e., illumination of the device is from the top of FIG. 1). Window layer 106 is electrically conductive and has a different composition than the active region. The bottom surface of window layer 106 and the top surface of active region 108 meet at a substantially planar interface, as shown. Window layer 106 has a larger band gap than the band gap of active region 108. In cases where active region 108 includes several layers having different compositions, the band gap of window layer 108 is larger than the band gap of the layer in active region 108 that is adjacent to window layer 106. In all cases, the band gap of window layer 106 is larger than the band gap of active region 108 at the interface between the window layer and the active region. The top surface of window layer 106 includes nano-structures 110, as shown.

Preferably, the active region and the window layer both include one or more compound semiconductors. Suitable materials include, but are not limited to: III-V semiconductors and II-VI semiconductors. Examples include AlGaAs window layer in GaAs solar cells, and CdS window in CdTe cells. Active region 108 preferably includes one or more p-n junctions. The example of FIG. 1 shows a single-junction cell, with n-type base 102 and p-type emitter 104. Nano-structured window layers as described herein are also applicable to multi-junction solar cells. The active region and the window layer are both preferably single-crystal or poly-crystalline, as opposed to being amorphous. The window layer is preferably of an indirect wide band gap material, to reduce optical absorption in the window layer.

The top surface of the window layer can be patterned to have any desired nano-structure shape. Suitable shapes include, but are not limited to: nano-cones, nano-pyramids and nano-domes. As used herein, nano-structuring refers to providing patterns having individual nano-features where the largest dimension of any individual nano-feature is less than 1 micron.

Preferably, the window layer is configured to provide optical anti-reflection due to the included nano-structures. Preferably, this anti-reflection capability is both broad-band and angle-insensitive. Methods for configuring nano-structure shapes to provide such capability are known in the art, and so are not described here. In preferred embodiments, no anti-reflection coating is disposed on the top surface of the window layer, thereby simplifying the device. In other embodiments, an anti-reflection coating can be disposed on the top surface of the nano-structured window layer, in order to further reduce reflection loss. Use of a nano-structured window layer can also advantageously lead to lateral light trapping in active layers of the solar cell. By scattering and/or diffraction from the nano-features of the window layer, normally incident light on the window layer can end up propagating more or less laterally in active device layers. This change in propagation direction can advantageously increase the effective optical thickness of light absorbing layers in the solar cell.

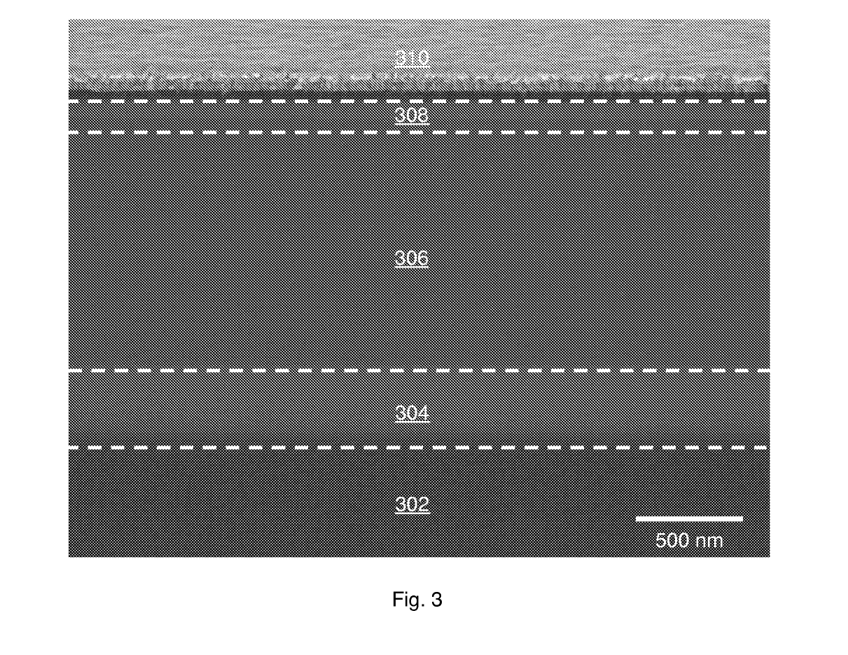

Preferably, the top surface of the window layer also includes planar regions for making electrical contact. Such planar regions are shown as 116 on FIG. 1. Here contact to window layer 106 is made via metal contact 114 (e.g., Ti/Pt/Au) and heavily-doped semiconductor 112 (e.g., P+ GaAs for an AlGaAs window layer). These planar contact regions are preferably configured as a grid having cells that include the nano-structures. The top view of FIG. 2 shows an example of this geometry. Here metal contact 114 is configured as a grid that defines cells, each cell including nano-structures 110 formed in window layer 106. This approach can provide high lateral conductance combined with minimal blocking of incident light by metal 114. Making metal contact on flat top surfaces of the window layer can provide low contact resistance and low junction leakage current.

### B) Experimental Demonstration

### B1) Results and Discussion

The device of this work is generally as shown on FIG. 1, where layer 102 is an n-type GaAs base, layer 104 is a p-type GaAs emitter, and window layer 106 is AlGaAs. The nano-structures 110 in this example are nano-cones. The AlGaAs nanocone arrays are on top of a planar GaAs p-n junction, separated by metal grid mesas. The nanocone etched structure was processed by a plasma etch with nanosphere silica masking, as is known in the art. FIG. 3 shows a tilted cross-section Scanning Electron Microscope (SEM) image of the metal grid mesa. Here base 302 is n-type GaAs with doping 2e17 cm⁻³ and is 3000 nm thick. Emitter 304 is p-type GaAs with doping 1e18 cm⁻³ and is 300 nm thick. Window layer 306 is p-type Al_{0.8}Ga_{0.2}As with doping 2e18 cm⁻³ and is 1100 nm thick (in the unpatterned mesa regions). Contact layer 308 is p-type GaAs with doping 2.5e19 cm⁻³ and is 100 nm thick. Metal layer 310 is Ti/Pt/Au (40/40/80 nm) having a total thickness of 160 nm.

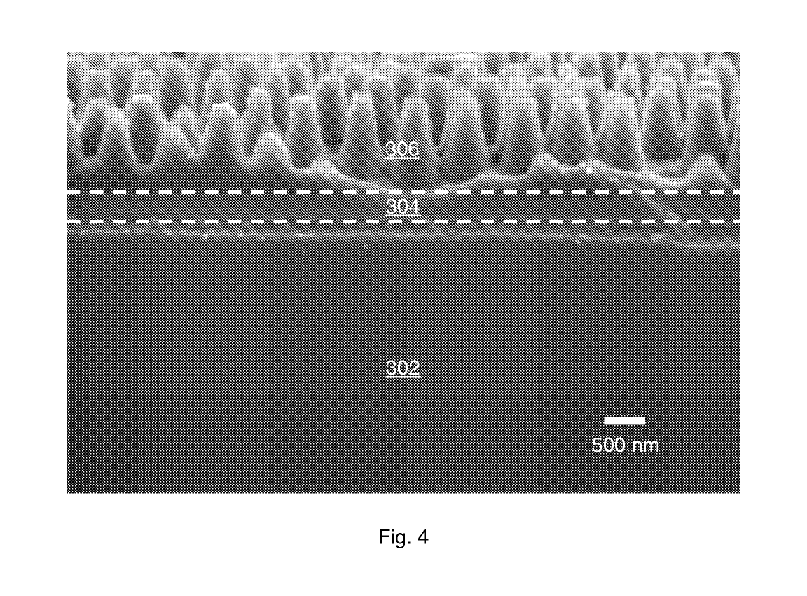

FIG. 4 shows a tilted cross-section SEM image of the AlGaAs nanocones between these metal mesas. Each nanocone is ˜900 nm in height and ˜650 nm in width. A planar control cell was made with a ˜100 nm-thick flat window layer while other parameters were maintained identical with this nanostructured cell.

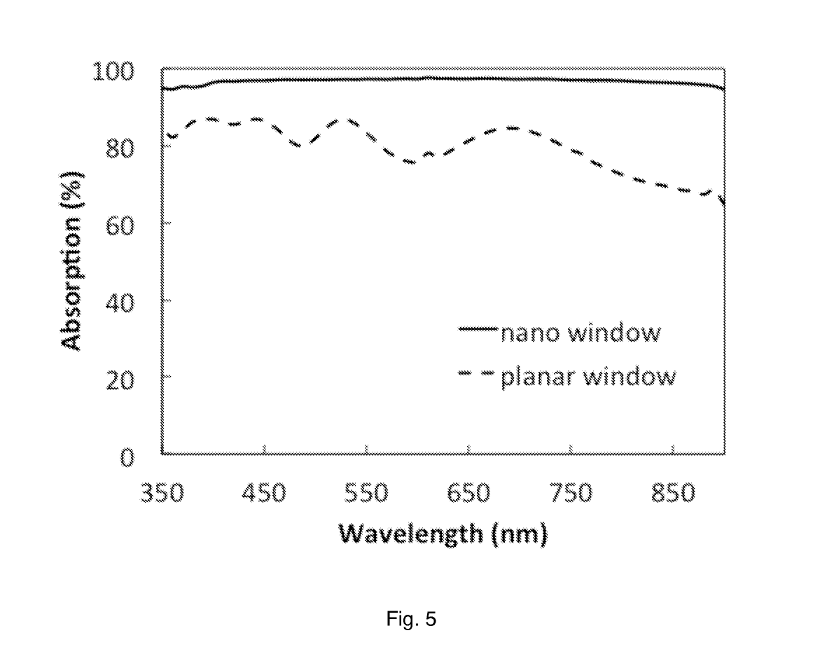

FIG. 5 shows the optical absorption of a nanocone AlGaAs window solar cell (solid line) compared to the planar control cell (dashed line), measured with a standard integrating sphere. The AlGaAs nanocones produce both excellent antireflection and light trapping effects. The nanocone window cell maintains a very high absorption of about 97% across the whole spectrum from 400 nm to 880 nm.

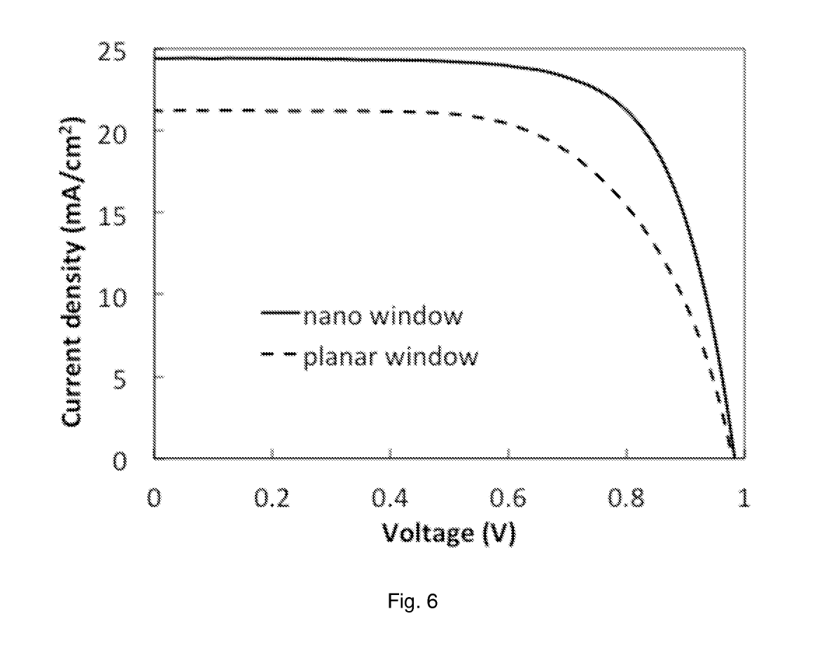

FIG. 6 shows photocurrent density versus voltage (J-V) curves measured under AM 1.5 G normal illuminations (1000 W/m², 1 sun) at room temperature. The solid line is for the nano-structured solar cell, and the dashed line is for the planar control. Compared to the planar control, the short circuit current (J_{sc}) in the nanostructured cell is improved from 21 mA/cm² to 24 mA/cm² (a 15% improvement). V_{oc} is slightly increased from 0.979 V to 0.982 V. FF (fill factor) is improved from 63% to 71%. The overall energy conversion efficiency is boosted from 13.1% to 17.0%, which in total is a 30% improvement. With potentially large angle acceptance, the improvement on electricity yield throughout the day can be even higher than 30%. Compared to conventional planar structures, this AlGaAs nanostructured window layer solar cell has advantages such as antireflection effect, enhanced carrier confinement and improved lateral conductance. Compared to radial p-n junction nanostructured solar cells, this nanostructured window layer design preserves low junction area and high material quality in solar cell p-n junctions.

Solar cells with nanostructured radial p-n junctions generally result in degraded V_{oc} and FF. In contrast, our nanostructured window design results in a high V_{oc} of 0.982 V and FF of 71%. The V_{oc} is 69% of GaAs band gap (1.42 eV), or only 0.438V lower than the band gap, benefited from a low junction area and a low dark current. In a nanostructured solar cell with radial junctions, without considering the series and shunt resistance, V_{oc} can be expressed as

$${V}_{oc} = \frac{{mk}_{B} T}{q} ln [ ( \frac{{J}_{sc}}{{J}_{0} Γ} ) + 1 ]$$

where m is the diode ideality factor that is close to 1 for a good diode, J₀ is the dark saturation current density, and Γ is the area of the junction in the cylindrical geometry relative to the area of the cylinder base area. The higher the aspect ratio, the more loss in V_{oc}. Planar structured solar cells have Γ=1. High aspect ratio nanowire solar cell with radial p-n junctions have a Γ that is significantly larger, thus lowering the V_{oc}. In our nanostructured window design, the nanostructures only exist on the emitter side, away from the junction region. The junction area is the same as the planar solar cell, i.e., Γ=1. Therefore, V_{oc} should be fundamentally higher for the nanostructured window layer solar cell than conventional nanostructured solar cells based on radial p-n junctions. Compared to the planar control solar cell, the open circuit voltage is even slightly improved, due to the contribution of the larger photocurrent. With J_{sc} improved by 15%, the calculated V_{oc} change is 0.003 V, assuming m=1.

In addition to the minimized junction area and higher photocurrent, another benefit from nanostructured window design that increases V_{oc} is minimizing the dark saturation current J₀, which is given by

$${J}_{0} = \frac{{qD}_{n} {n}_{{p}_{0}}}{{L}_{n}} + \frac{{qD}_{p} {p}_{{n}_{0}}}{{L}_{p}} .$$

Here Lₙ and Lₚ are the diffusion lengths of electrons and holes, respectively. The quantities nₚ_{₀} and pₙ_{₀} are the minority electron density in the p-region and the minority hole density in the n-region at thermal equilibrium, respectively. Dₙ and Dₚ are the electron and hole diffusivities. High recombination sources close to the junction allow carriers to move to this recombination source very quickly and recombine, thus dramatically reducing the diffusion length. Because the nanostructure in the window layer is fabricated after epitaxial growth, the material quality in p-n junction, in terms of carrier life time or diffusion length, is maintained the same as a planar cell. Therefore Lₙ and Lₚ are the appropriate dimensions rather than the small radial layer thickness of a nanowire structure and the diffusion lengths are sufficiently large to ensure low J₀.

The preferred metal grid mesa design also helps maintain high V_{oc}. Depositing metal on nanostructured surface can introduce defects and traps at the metal/semiconductor interface, which increase the recombination current and reduce the quasi-Fermi level near the metal contact. In our design, the metal contact was formed before the nanocone etching. Therefore the contact interface is not disrupted by the nanostructures.

The improvement of the fill factor is mainly from the reduced series resistance and large shunt resistance realized by uniform planar Ohmic contacts and increased lateral conductance. The series resistance is improved from 5.8 Ω·cm² to 3.9 Ω·cm², because the nanostructured AlGaAs window is thicker in average than its planar counterpart. The shunt resistance of the nano-structured cell is measured to be about the same as the planar cell, about 1×10⁴ Ω·cm². Reducing shunting has been challenging for conventional nanostructured solar cell contact fabrication. Insulating layers such as poly (methyl methacrylate) (PMMA) and benzocyclobutene (BCB) have been used in such conventional devices to prevent leakage by direct contact of the top metal with substrate in nanostructured III-V solar cells. In contrast, the present approach can eliminate this shunting issue by simply maintaining a planar structure at the contact region, while having the nano-structures elsewhere.

The 15% enhancement in short circuit current benefits from the improved light absorption. Though absorption is enhanced over the broad sun spectrum due to suppressed reflection and light trapping, harvesting these increased number of excited electron-hole pairs and transferring them into current is equally important, i.e. high internal quantum efficiency is desired. According to number of absorbed photons calculated from the measured optical absorption, the J_{sc} improvement could be up to 40%, or even approaches 50% relative to a 32.4 mA/cm² at Shockley-Queisser limit for ideal GaAs solar cell, assuming the same internal quantum efficiency for planar and nanostructured solar cells. This loss is from the recombination in AlGaAs nanocones, which is an expected trade-off. However, if we assume 100% carrier recombination in the AlGaAs nanocones (i.e., a worst case), the improvement in J_{sc} would be significantly less than what was observed.

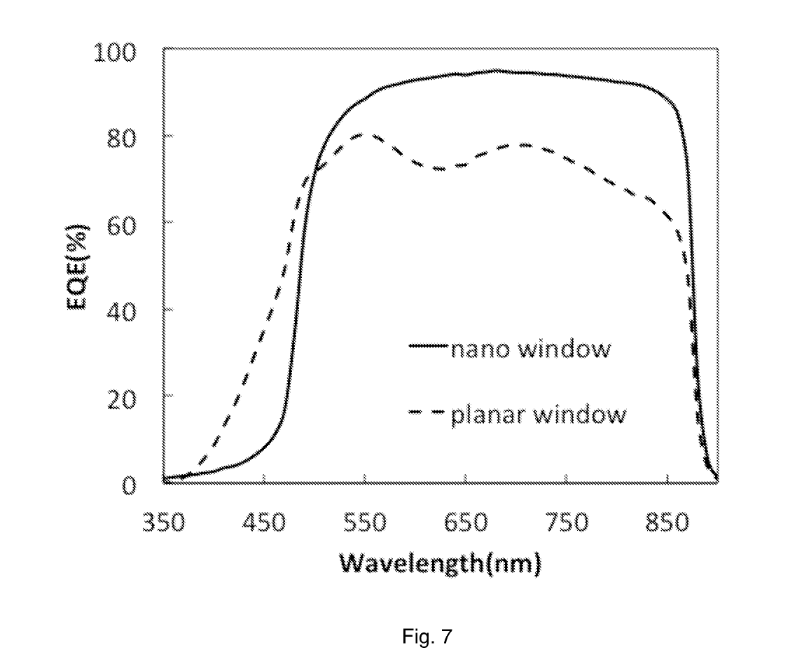

FIG. 7 shows the external quantum efficiency (EQE) from 350 nm to 900 nm for a nanocone AlGaAs window solar cell (solid line) and a planar cell with a 100 nm AlGaAs window (dashed line). Compared to the planar control cell, for wavelengths below 500 nm (blue part of the spectrum), the nanostructured cell EQE is lower than the planar cell due to the loss in AlGaAs itself. However, the EQE from 500 nm to 880 nm is broadly increased. Especially at the long wavelengths, this improvement is about 50%. Over 90% of EQE in the nanostructured window cell is obtained from 550 nm to 850 nm, indicating both strong absorption and efficient charge separation at these wavelengths.

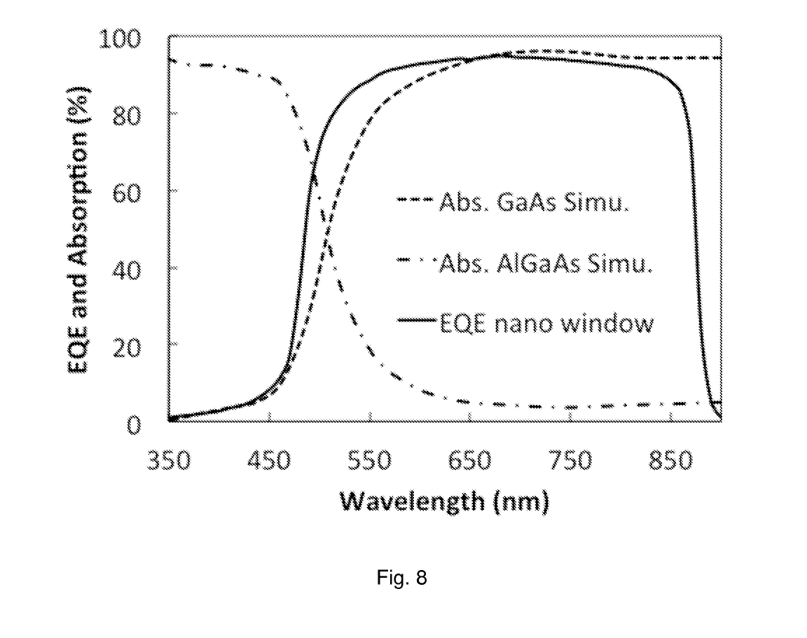

To investigate if the electron hole pairs generated in the AlGaAs nanocones actually partially transfer into current instead of totally recombining, light absorption in the AlGaAs nanocone window and in the GaAs active layer were simulated using a Finite Difference Time-Domain Method (FDTD) and plotted against the experimental EQE, as shown in FIG. 8. According to the simulation, for wavelengths above 550 nm, most absorption is in the GaAs (dashed line) and almost no absorption is in the AlGaAs nanocone window (dash-dot line). Light transmitted into GaAs junction has been efficiently transferred into current. However, at wavelengths near 500 nm, the EQE (solid line) is much higher than the absorption in GaAs. This offset has to be contributed by the carriers excited in AlGaAs nanocone window.

The spatial distribution of generated electron-hole pairs in the nano-cones has also been investigated using FDTD simulations. The AlGaAs nanocone tends to ‘focus’ most of incident light into a small region below it, where a cluster of high concentrated photons is observed. Several absorption centers are formed inside the AlGaAs nanocone. The carriers excited by the absorption center near the bottom of the nanocone tend to be more likely to diffuse down into GaAs p-n junction while those in the top center where electron-hole pairs are closer to the surface mostly recombine. At longer wavelengths, these absorption centers tend to shift downward. At 450 nm, due to the high absorption coefficient, most of absorption occurs near the tip of nanocones. At 490 nm, the middle absorption center becomes more dominant and another center near the base of nanocone becomes more obvious. The EQE at 490 nm is 59%, while GaAs absorption is only 27%, thus at least 32% in 59% is from the carriers collected from AlGaAs nanocones. At 510 nm, the three absorption centers are roughly at same intensity as the centers of absorption moved even further down. The EQE is 78%, GaAs absorption is 48%. Thus, at least 30% in 78% EQE is actually attributed to the carriers collected from AlGaAs nanocones. For longer wavelength at 540 nm and 600 nm, the absorption center shifted down into GaAs near the AlGaAs/GaAs heterojunction interface.

Therefore, a fraction of the absorbed light in the AlGaAs nanocone window actually transfers into the real current though a larger fraction suffers from recombination. Recombination mechanisms in AlGaAs nanostructures include radiative recombination, Shockley-Read-Hall (SRH) recombination, Auger recombination and surface recombination. Because the carrier concentration in nanostructure is high due to light trapping, recombination near nanostructures should be considered as high level injection. Radiative recombination contributes to photon recycling and eventually external fluorescence, which is favorable for high efficiency solar cells. SRH recombination saturates at high level injection due to limited traps. Surface recombination and Auger recombination can be the most harmful in nanostructures. According to a recent work on recombination mechanisms in nanostructured black Si solar cell, Auger recombination plays an important role in nanostructures especially at high doping levels. In the upper center of nanocones where light is trapped, the local minority carrier density is even higher, resulting in more severe Auger recombination. Therefore, optimal doping levels in nanostructured window should be relatively lower than conventional planar window layers.

Other than high aluminum content AlGaAs, conventional GaAs solar cells also use In_{0.51}Ga_{0.49}P as the window layer, which is also lattice matched to GaAs. Both In_{0.51}Ga_{0.49}P and Al_{0.8}Ga_{0.2}As have low surface recombination rates in the order of 10⁴ cm/s. The rate in In_{0.51}Ga_{0.49}P is even slightly lower. However, for nanostructured window layer design, Al_{0.8}Ga_{0.2}As outperforms In_{0.51}Ga_{0.49}P, as our best In_{0.51}Ga_{0.49}P nanostructured window cell fabricated with the same geometry is only 10.2% in efficiency. This is because the blue spectrum loss is much smaller in Al_{0.8}Ga_{0.2}As than in In_{0.51}Ga_{0.49}P. Al_{0.8}Ga_{0.2}As has a band gap of 2.09 eV, corresponding to 593 nm in wavelength, however, because it is an indirect band gap, the absorption edge is not actually at 593 nm. Instead, it is at 480 nm, corresponding to 2.585 eV, which is the direct band gap between the Γ valley conductance band minimum and the valance band maximum. Therefore, the AlGaAs is not so absorptive for wavelength that is longer than 480 nm. This is consistent with EQE measurement, which shows an abrupt change near 480 nm. In contrast, although In_{0.5}Ga_{0.49}P has a similar band gap of 1.9 eV, because it has a direct band gap, its absorption edge is right at 650 nm. Therefore, the EQE between 480 nm to 650 nm is much lower.

To conclude, we have demonstrated a 17% efficiency GaAs solar cell with AlGaAs nanocone window layer. Absorption is significantly enhanced without any additional antireflection coatings. With carrier confinement from AlGaAs nanocone window layer, the enhanced absorption transfers to a EQE of 90%-95% from 550 nm to 850 nm and further to a 15% improvement in J_{sc}. V_{oc} of 0.982 V is achieved with high-quality, low-area junction and minimized the dark current. FF is improved by metal mesa grid design which avoids shunting contact on nanostructured surfaces. A trade-off between EQE at blue spectrum and at long wavelength spectrum exists due to the recombination of trapped carriers inside nanostructures. However, offset between EQE and absorption simulation suggests charge transferring from AlGaAs nanocones to GaAs junctions, which partially compensate the expected loss in AlGaAs. Indirect band gap nature of high Al content AlGaAs makes it a better candidate than InGaP in nanostructured window layer GaAs solar cells. By optimizing the geometry AlGaAs nanostructures, effectively passivating the nanostructure surface and adjusting its doping concentrations, it is possible to achieve over 20% efficiency nanostructured solar cell which even approaches the Shockley-Queisser limit.

### B2) Methods

### B2a) Solar Cell Fabrication

A GaAs solar cell with AlGaAs window was first grown on n-type GaAs substrate with metal organic chemical vapor deposition (MOCVD). The GaAs solar cell device has a 300 nm thick emitter with p type doping of 1×10¹⁸ cm⁻³, a 3000 nm base with n type doping of 2×10¹⁷ cm⁻³. A 50 nm back side field (BSF) layer of n type Al_{0.3}GaAs with equal doping was added to the base for a purpose of minority carrier confinement. 1100 nm p-type Al_{0.8}Ga_{0.2}As window layer with doping of 2×10¹⁸ cm⁻³ was then deposited, which enable the subsequent nanocone etching. A 100 nm p type heavily doped GaAs layer of 2.5×10¹⁹ cm⁻³ was deposited on top of the AlGaAs window layer. All the III-V layers were deposited at 720 C. After MOCVD growth, a multilayer alloy film of Au/Ge/Ni/Au (40 nm/12 nm/12 nm/80 nm), designed for Ohmic contact with n type GaAs substrate, was deposited as back electrode with e-beam evaporation. Metal fingers of Ti/Pt/Au (40 nm/40 nm/80 nm) alloy, designed for Ohmic contact with p type GaAs, were deposited as the top electrodes.

### B2b) Nanostructured AlGaAs Window Layer Fabrication

Periodic nanocones in AlGaAs window layer were fabricated via nanosphere lithography. First, Langmuir-Blodgett assembly of monodisperse SiO₂ nanospheres were coated on top of the GaAs solar cell with patterned metal grids. During the coating, the orientation of the metal fingers was aligned vertically to avoid disruption of the surface tension while wafer immersion. The monolayer of nanospheres together with the metal fingers was then used as a mask for Chlorine based electron cyclotron resonance-reactive ion etching (ECR-RIE) of AlGaAs layer, forming metal grid mesa with AlGaAs nanocones in between. The etching was stopped when there was about 50 nm AlGaAs layer left under nanocones to maintain the complete coverage of AlGaAs window layer and junction passivation. After that, the device was dipped into an ammonium and hydroperoxide solution to smoothen the nanocone surface.

### B2c) Device Characterization

Absorption measurements were taken using a standard integrating sphere system. Incident light enters the sphere through a small port and illuminates the sample mounted in the center of the sphere. The reflected and transmitted light was scattered uniformly by the interior sphere wall. A silicon detector mounted at the back of the sphere produces a photocurrent of all the reflected and transmitted photons. With a reference photocurrent for the initial incident light, absorption can be calculated. J-V was measured under AM 1.5 G normal illuminations (1000 W/m², 1 sun) at room temperature. EQE was measured by shining a laser beam on the nanocone surface between metal mesa grids. Devices were illuminated by mechanically chopped monochromatic light lamp and the photocurrent was measured using a lock-in amplifier. The light intensity was calibrated using an amplified and calibrated Si photodetector. Solar cell J_{sc} was confirmed by integrating the EQE spectrum.

1. A solar cell comprising:
a semiconductor active region, wherein optical absorption in the active region provides electrical charge carriers;
a semiconductor window layer disposed on the active region, wherein light incident on the active region passes through the window layer, and wherein the window layer is electrically conductive;
wherein a bottom surface of the window layer and a top surface of the active region meet at a substantially planar interface;
wherein a top surface of the window layer opposite the bottom surface of the window layer includes nano-structures;
wherein the window layer has a different composition than the active region; and
wherein a band gap of the window layer is greater than a band gap of the active region at the interface.

2. The solar cell of claim 1, wherein the active region and the window layer both comprise one or more compound semiconductors.

3. The solar cell of claim 1, wherein the active region comprises one or more p-n junctions.

4. The solar cell of claim 1, wherein both the active region and the window layer are single-crystal or poly-crystalline.

5. The solar cell of claim 1, wherein the top surface of the window layer comprises one or more shapes selected from the group consisting of: nano-cones, nano-pyramids and nano-domes.

6. The solar cell of claim 1, wherein the window layer provides optical anti-reflection due to the included nano-structures.

7. The solar cell of claim 1, wherein no anti-reflection coating is disposed on the top surface of the window layer.

8. The solar cell of claim 1, wherein the top surface of the window layer further includes planar regions for making electrical contact.

9. The solar cell of claim 8, wherein the planar regions are configured as a grid having cells that include the nano-structures.

10. The solar cell of claim 1, wherein the window layer has an indirect band gap.
